(19) United States
(12) Patent Application Publication
(10) Pub. No.: US 2015/0140701 A1
(43) Pub. Date: May 21, 2015

(54) METHOD FOR MANUFACTURING LIGHT EMITTING DIODE PACKAGE

(71) Applicant: ADVANCED OPTOELECTRONIC TECHNOLOGY, INC., Hsinchu Hsien (TW)

(72) Inventors: CHIEN-CHUNG PENG, Hukou (TW); TZU-CHIEN HUNG, Hukou (TW)

(21) Appl. No.: 14/542,872

(22) Filed: Nov. 17, 2014

(30) Foreign Application Priority Data
Nov. 20, 2013 (CN) 201310583729.1

(51) Int. Cl. H01L 33/50; H01L 33/58; H01L 33/54

(52) U.S. Cl. CPC H01L 33/507; H01L 33/54; H01L 33/58; H01L 2933/0041; H01L 2933/005; H01L 2933/0058
USPC 438/27

(57) ABSTRACT

A method for manufacturing an LED (light emitting diodes) package includes providing a substrate having electrodes; providing an LED chip, the LED chip arranged on the substrate and electrically contacting the electrodes; providing an UV-curing adhesive layer, the UV-curing adhesive layer arranged on the substrate and entirely packaging the LED chip and the electrodes therein, and then the UV-curing adhesive layer being solidified.

### FIELD

The subject matter herein generally relates to semiconductor devices and, more particularly, to a method for manufacturing a light emitting diode (LED) package.

### BACKGROUND

A conventional method for manufacturing an LED package includes the following steps, such as providing an LED chip and a substrate, adhering the LED chip to the substrate, electrically coupling the LED chip and the substrate by wire bonding, packaging the LED chip and the substrate by glue, and drying the glue. However, the processes are complicated and time-consuming.

### BRIEF DESCRIPTION OF THE DRAWINGS

Implementations of the present technology will now be described, by way of example only, with reference to the attached figures.

FIG. 1 is a cross-sectional view of an LED package of an exemplary embodiment of the present disclosure.

FIG. 2 is a flow chart of a method for manufacturing the LED package of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series and the like.

The present disclosure is described in relation to a method for manufacturing an LED package.

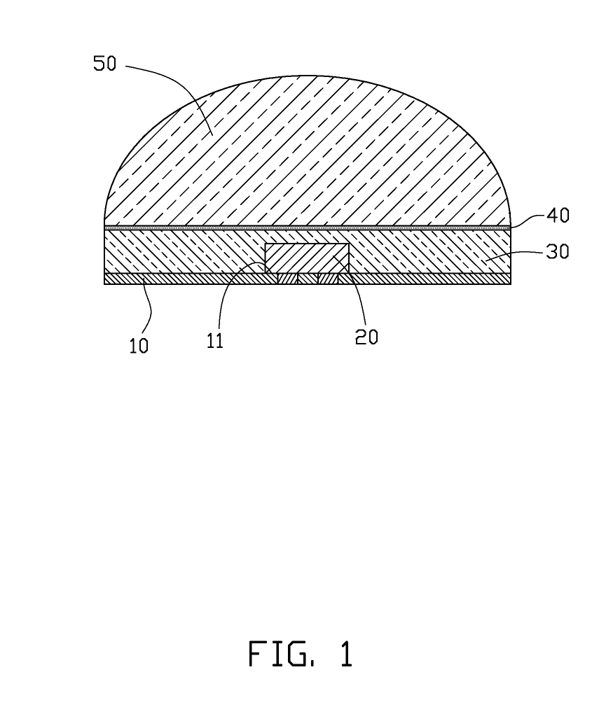

Referring to FIG. 1, the LED package includes a substrate 10, two electrodes 11 embedded in the substrate 10, an LED chip 20 arranged on the substrate 10 and electrically contacting the electrodes 11, a UV-curing adhesive layer 30 packaging the LED chip 20, a phosphor layer 40 formed on a top of the UV-curing adhesive layer 30 and a light guiding member 50 formed on the phosphor layer 40.

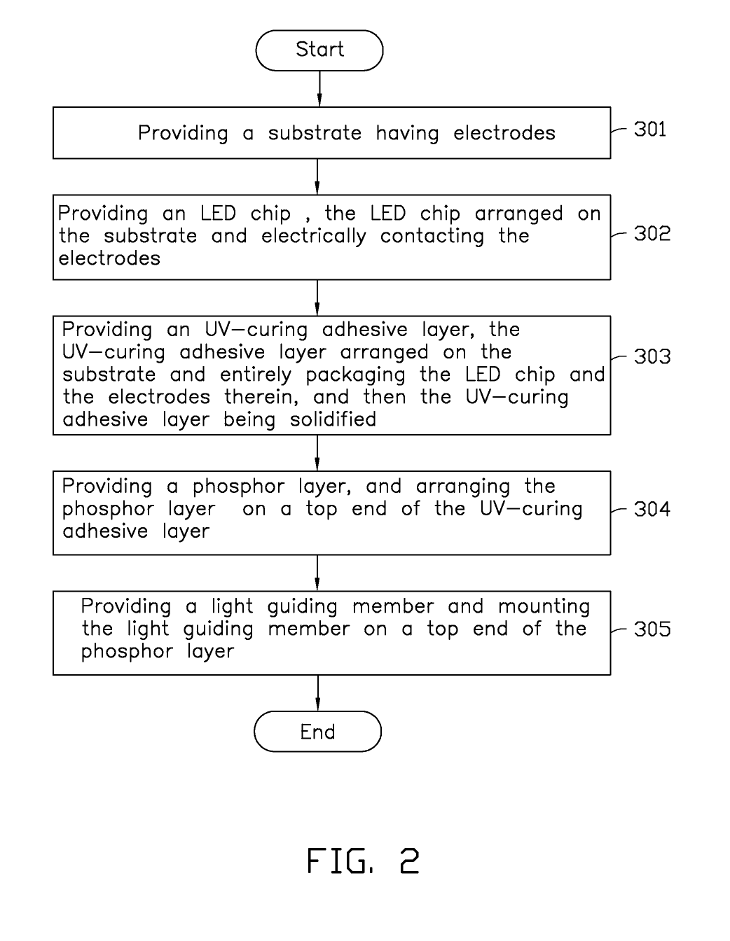

Referring to FIG. 2, a flowchart is presented in accordance with an embodiment of a method for manufacturing the LED package. The method is provided by way of example, as there are a variety of ways to carry out the method. The method described below can be carried out using the configurations illustrated in FIG. 1, for example, and various elements of these figures are referenced in explaining the method. Each block shown in FIG. 2 represents one or more processes, methods, or subroutines, carried out in the method. Furthermore, the illustrated order of blocks is illustrative only and the order of the blocks can be changed. Additional blocks can be added or fewer blocks may be utilized without departing from this disclosure. The method can begin at block 301.

At Block 301, the substrate 10 having electrodes 11 is provided. The substrate 10 has good heat dissipation efficiency and is made of silicon, graphite, aluminum oxide, titanium oxide, ceramics, or metal. A number of the electrode 11 can be two. The two electrodes 11 are embedded in a central portion of the substrate 10 and extend through the substrate 10 from top to bottom. Top and bottom surfaces of each electrode 11 are respectively coplanar to top and bottom surfaces of the substrate 10.

At Block 302, the LED chip 20 is provided, is arranged on the substrate 10 and electrically contacts the electrodes 11.

At Block 303, the UV-curing adhesive layer 30 is provided, the UV-curing adhesive layer 30 is arranged on the substrate 10 and entirely packages the LED chip 20 and the electrodes 11 therein, and then the UV-curing adhesive layer 30 is solidified. The solidified UV-curing adhesive layer 30 makes the LED chip 20 electrically connected to the electrodes 11.

At Block 304, the phosphor layer 40 is provided and arranged on a top end of the UV-curing adhesive layer 30. Light emitted from LED chip 20 acts on phosphor of the phosphor layer 40 to obtain desired color light. In this embodiment, the LED chip 20 is a blue LED chip, and the phosphor layer 40 is a yellow phosphor layer.

At Block 305, the light guiding member 50 is provided and mounted on a top end of the phosphor layer 40. In this embodiment, the light guiding member 50 is used to adjust the light distribution of the LED chip 20. The light guiding member 50 is hemispherical.

In this state, the LED package is manufactured completely.

The embodiments shown and described above are only examples. Many details are often found in the art such as the other features of an LED package. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A method for manufacturing an LED (light emitting diodes) package comprising:
providing a substrate having electrodes;
providing an LED chip , the LED chip arranged on the substrate and electrically contacting the electrodes;
providing a UV-curing adhesive layer, the UV-curing adhesive layer arranged on the substrate and entirely packaging the LED chip and the electrodes therein, and then the UV-curing adhesive layer being solidified.

2. The method as claimed in claim 1, wherein the substrate is made of silicon, graphite, aluminum oxide, titanium oxide, ceramics, or metal.

3. The method as claimed in claim 1, wherein top and bottom surfaces of each electrode are respectively coplanar to top and bottom surfaces of the substrate.

4. The method as claimed in claim 1 further comprising providing a phosphor layer, and arranging the phosphor layer on a top end of the UV-curing adhesive layer.

5. The method as claimed in claim 4 further comprising providing a light guiding member and mounting the light guiding member on a top end of the phosphor layer.

6. A method for manufacturing an LED (light emitting diodes) package comprising:
providing a substrate having electrodes;
providing an LED chip , the LED chip arranged on the substrate and electrically contacting the electrodes;
providing a UV-curing adhesive layer, the UV-curing adhesive layer arranged on the substrate and packaging the LED chip and the electrodes therein, and then the UV-curing adhesive layer being solidified.

7. The method as claimed in claim 6 further comprising providing a phosphor layer, and arranging the phosphor layer on a top end of the UV-curing adhesive layer.

8. The method as claimed in claim 7 further comprising providing a light guiding member and mounting the light guiding member on a top end of the phosphor layer.

9. The method as claimed in claim 8, wherein the light guiding member is hemispherical.
